(19) United States
(12) Patent Application Publication
(10) Pub. No.: US 2024/0399503 A1
(43) Pub. Date: Dec. 5, 2024

(54) METHOD FOR GENERATING NANOPARTICLES ON THE SURFACE OF A SUBSTRATE AND PART COMPRISING SUCH A SUBSTRATE

(71) Applicants: HYDROMECANIQUE ET FROTTEMENT, ANDREZIEUX BOUTHEON (FR); Université Jean Monnet Saint Etienne, ST ETIENNE CEDEX 2 (FR); UNIVERSITE CLAUDE BERNARD LYON 1, VILLEURBANNE (FR); Institut National des Sciences Appliquées Lyon (INSA Lyon), Villeurbanne Cedex (FR); UNIVERSITE DE LORRAINE, NANCY CEDEX (FR); CENTRE NATIONAL DE LA RECHERCHE SCIENTIFIQUE (CNRS), PARIS CEDEX 16 (FR)

(72) Inventors: Marie-Alix LEROY, SAINT-ETIENNE (FR); Christophe Gérard PUPIER, GENAS (FR); Solène DASSONNEVILLE, MARSEILLE (FR); Philippe STEYER, FOUR (FR); Alejandro BORROTO, SAINT-BRIEUC (FR); Stéphanie BRUYÈRE, SAULXURES LES NANCY (FR); Jean-François PIERSON, MOIVRONS (FR); Mathilde PRUDENT, Le François, Martinique (FR); Jean-Philippe COLOMBIER, Saint-Héand (FR); Florent BOURQUARD, SAINT-ETIENNE (FR); Florence GARRELIE, SAINT-ETIENNE (FR)

(21) Appl. No.: 18/686,290

(22) PCT Filed: Sep. 8, 2022
(86) PCT No.: PCT/FR2022/051694

§ 371 Date: Feb. 23, 2024

(30) Foreign Application Priority Data
Sep. 8, 2021 (FR) FR2109406

(51) Int. Cl. B23K 26/352; B23K 26/00; B23K 26/0622

(52) U.S. Cl. CPC B23K 26/352; B23K 26/0006; B23K 26/0622

(57) ABSTRACT

A process for generating nanoparticles on the surface of a substrate includes a step of providing the substrate made of a material including at least one element from columns 4, 5, 13 and 14 of the periodic classification, and at least one noble or transition metal; a step of irradiating the substrate by laser, with a pulse duration between 1 fs and 100 ps, a pulse between 0.01 J/cm² and 100 J/cm², a wavelength between 100 nm and 5000 nm, and a number of pulses per point between 1 and 1000; and a step of generating at least one nanoparticle on the surface of the substrate, the at least one nanoparticle including at least the noble or transition metal, and having a different chemical composition from that of the substrate. Also disclosed is a part including such nanoparticles.

### TECHNICAL FIELD

The invention relates to a surface functionalization process, i.e., a method for adding at least one property to a surface to give it at least one new function, for example to increase its chemical reactivity.

It relates more specifically to a surface functionalization process by generating nanoparticles on the surface of a substrate made of a given material.

### CONTEXT AND PRIOR ART

Generating nanoparticles (i.e., particles of which the characteristic size is less than some hundreds of nanometers) on a surface of a substrate made of a given material, referred to as base material, makes it possible to give the material thus treated new functions. This is in particular on account of the fact that the specific surface area obtained is greater than that of the material before treatment, and the fact that, thanks to their very small size, the nanoparticles have a greater proportion of low-coordination atoms (located on the edges or vertices of the nanoparticle), which renders them particularly reactive (large number of active sites). Furthermore, adding a nanostructure to the surface of a material modifies its wettability properties: hydrophilic or very hydrophobic surfaces may thus be obtained in a controlled manner.

Such functions may impart an advantage of interest for an antimicrobial (antibacterial or virucidal) surface, for example.

Furthermore, exposing on the surface, in the form of nanoparticles, Cu or Ag for example (elements known for their antimicrobial properties), makes it possible to increase the reactivity of the surface thus treated with respect to the degradation and destruction of microorganisms coming into contact with it. This enables a decrease in contamination in environments with a high human concentration, induced by touching contaminated objects (reduction of healthcare-associated infections in hospital, medical settings, for example). This treatment may be applied for example on parts in regular contact with hands, such as a door handle or sign, a hand rail, a bar, a faucet, or on a ventilation, or water purification, system, or others.

Functionalizing a surface may also make it possible to produce catalytic surfaces, in the context of heterogeneous catalysis, with applications in environmental catalysis, industrial chemistry and fine chemicals.

This is for example possible by creating, on the surface, nanoparticles of elements having known catalytic properties for the sought reactions (noble or transition metals).

Creating nanoparticles of noble metals (for example gold (Au), silver (Ag), copper (Cu), platinum (Pt), or palladium (Pd)) is also of interest in the field of plasmonics, with applications in molecule detection in biology, medicine, catalysis, by devices using the surface plasmon resonance of these nanostructures.

The generation of nanoparticles on the surface of a support material (here referred to as substrate) may be carried out according to different methods.

The most common are performed via an external supply of material generating the nanoparticles. The deposition may be performed by dipping, coating, centrifugation or by electrophoresis with a solution charged with nanoparticles.

Alternatively, the nanoparticles may be generated in-situ using the supplied material: this is the case of electrodeposition, gas phase deposition or vacuum evaporation, frequently followed by high-temperature annealing.

A drawback of these different methods is the weakness of the adherence of the nanoparticles on their support: as the particles are simply placed on the surface of the treated material, they are capable of becoming detached during the use of the part in question and being released into the environment.

A further problem associated with a use of nanoparticles dispersed on a substrate is their tendency toward growth, agglomeration and “coking”, i.e., the accumulation of carbon on the surface of metallic nanoparticles in hydrocarbon environments, which renders them less chemically active.

Furthermore, deposition by coating with a solution charged with nanoparticles implies preparing and handling nanoparticles in advance, which creates a risk for an operator's health.

To avoid these different weaknesses, it has been envisaged to generate nanoparticles from the support material.

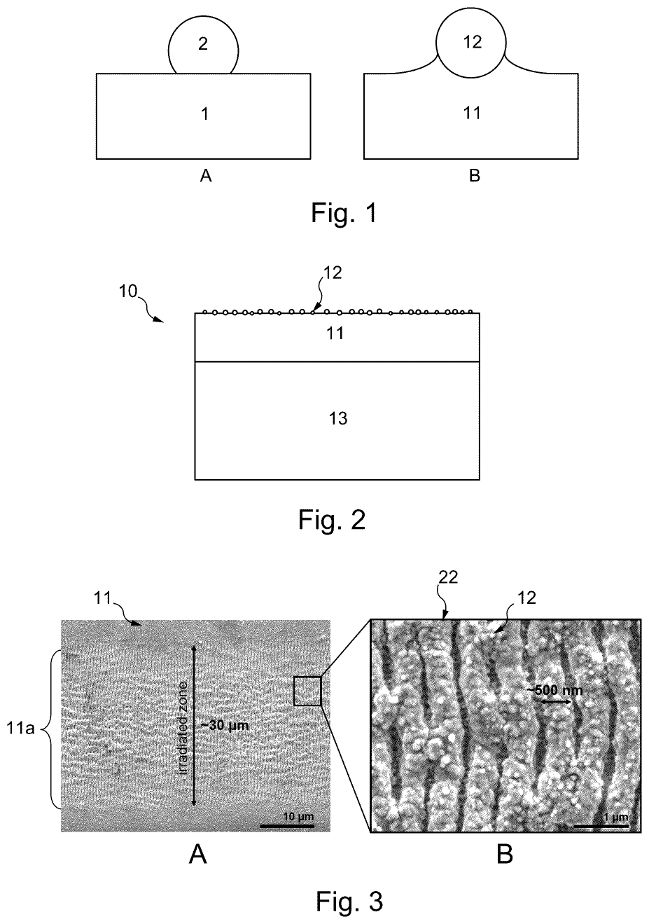

FIG. 1 illustrates such a principle very schematically: instead of obtaining nanoparticles deposited on the base material (on the surface of the substrate) as represented in FIG. 1A, the nanoparticles are generated from the material of the substrate, as represented in FIG. 1B, which gives them a better anchorage on the surface of the substrate.

For this, one process developed relatively recently is for example redox exsolution of nanoparticles (also known as solid phase recrystallization).

The document GB2566104 (A) describes for example a process wherein a catalytically active transition metal is substituted in the B sites of perovskite crystals of general formula ABO₃ under oxidizing conditions (for example nickel (Ni) in a perovskite LaₓSr_{1-3x/2}TiO₃, where La denotes lanthanum, Sr strontium, Ti titanium and O oxygen), then the material obtained is heated to high temperature in a reducing atmosphere, which induces the release of metallic nanoparticles (Ni in this example) on the surface of the perovskite, from the volume thereof. The particles thus obtained have a strong interaction with the support, wherein they are rooted, which results from their growth from the support material. This process is however limited to the substrate treatment of compositions and crystalline phase described above.

A laser irradiation process has also been proposed for the generation of nanoparticles from a metallic surface; the nanoparticles then have the same chemical composition as the irradiated substrate material: Ag nanoparticles formed on an Ag surface, Cu nanoparticles formed on a Cu surface. This is for example described in the document CA2874686 (A1).

The following articles also concern different processes for generating nanoparticles on a surface:
Hamad et al. Femtosecond Laser-Induced, Nanoparticle-Embedded Periodic Surface Structures on Crystalline Silicon for Reproducible and Multi-utility SERS Platforms, ACS Omega 3 (2018) 18420-18432;
Neagu, D. et al. Nano-socketed nickel particles with enhanced coking resistance grown in situ by redox exsolution. Nat. Commun. 6 (2015) 8120;
Guay J.M. et al., Laser-induced plasmonic colours on metals, Nature communications 8 (2017) 16095;
Fan et al. J. Appl. Phys. 115, 124302 (2014), and J. Appl. Phys. 114, 083518 (2013);
Mohan et al., Applied Physics A; Materials Science & Processing, Springer, Berlin, DE, vol. 86, no. 1, Oct. 28, 2006, pages 73-82.

### Aims—Technical Problems to be Solved

An aim of the present invention is therefore that of forming nanoparticles having a good adherence, over time, to the surface on which they are generated, in particular for nanoparticles including chemical elements having catalytic, antimicrobial and/or plasmonic properties of interest, i.e., for example noble or transition metals.

A further aim is that of providing a functionalization process that is simple and industrializable, undemanding in terms of cost, treatment conditions and parts that can be treated (shape, chemical nature, thermal or chemical resistance).

A further aim is that of providing a process making it possible to avoid handling nanoparticles.

An even further aim is that of providing a local functionalization of the treated surface, while being capable of finely selecting the zones of the surface to be treated, possibly with a micrometric resolution, and having a low impact on a volume of the part.

### Disclosure of the Invention

To achieve, at least in part, the aims cited above, according to a first aspect of the invention, a process for generating nanoparticles on the surface of a substrate is proposed, the process including:
a step of providing the substrate having a free surface, the substrate being made of a material having a chemical composition including:
   at least one element from columns 4, 5, 13 and 14 of the periodic classification of elements, in particular at least one element from among Ti (titanium), Zr (zirconium), Hf (hafnium), Nb (niobium), Ta (tantalum), V (vanadium), Al (aluminum), or Si (silicon), preferably Ti and/or Zr;
   at least one noble metal or one transition metal, in particular at least one noble metal or one transition metal from columns 8 to 11 of the periodic classification of elements, in particular at least one from among Au (gold), Ag (silver), Pt (platinum), Pd (palladium), Cu (copper), Fe (iron), Co (cobalt), Ni (nickel), preferably Cu, Ag and/or Au;
a step of irradiating at least a part of the free surface of the substrate by a laser radiation source producing a pulsed radiation, with a pulse time between 1 fs and 100 ps, a pulse fluence between 0.01 J/cm² and 100 J/cm², a wavelength between 100 nm and 5000 nm, and a number of pulses per point treated between 1 and 1000; and
a step of generating at least one nanoparticle on the free surface of the substrate from the material of the substrate, the at least one nanoparticle including at least the noble metal or the transition metal, and having a different chemical composition from that of the substrate.

A nanoparticle denotes here a particle of which a characteristic size is less than some hundreds of nanometers.

The present invention thus proposes an alternative in-situ nanoparticle generation solution to the known processes described above, by segregating chemical elements of the material of the substrate.

The process uses an extremely localized (in position and in depth) heating applied to the surface of the material, which induces the formation of nanoparticles on the treated surface.

Indeed, so-called ultrashort laser irradiations induce a localized heating of the treated surface: the laser-material interaction takes place over a typical depth of around fifteen nanometers, and the energy supplied is propagated in the form of heat and pressure waves over a typical depth of around one hundred nanometers in the material of the substrate treated.

Under the effect of this treatment, the material from the surface of the substrate (on a scale of around one hundred nanometers) is decomposed, and at least one constituent metallic element of the initial material of the substrate diffuses toward the surface of the substrate to form metallic nanoparticles.

Thanks to such a process, the nanoparticles are composed of a part of the chemical elements of the treated material, but have a different chemical composition from it (chemical segregation effect).

As these nanoparticles have a different chemical composition from that of the material of the substrate, it is possible to expose, on the surface of the material of the substrate, elements having different reactivity properties, generally more advantageous in a given context, than those of the material of the substrate.

For example, in order to impart at least one antimicrobial property to a surface, one possibility is that of generating copper (Cu) nanoparticles because Cu is an element having advantageous catalytic and antimicrobial properties (the same applies for silver (Ag)).

Thus, for example, if the base material is an alloy including at least zirconium (Zr) and copper (Cu), a treatment according to the invention induces a chemical segregation of Cu, in the form of nanoparticles, on the surface of the ZrCu alloy. As the chemical reactivity of the material thus treated is increased (thanks to the developed surface area facing the external environment which is greater on account of the addition of nanoparticles, and to the greater reactivity of the nanoparticles compared to the reactivity of the base material), a chemically active surface is thus obtained: i.e., which makes it possible to accelerate or enable a sought chemical reaction, for example for an antimicrobial function.

These application examples are not restrictive, and the process can be used in other scopes where a surface functionalization by nanostructures, and in particular nanoparticles, may be required.

This process therefore has several advantages over other processes for obtaining nanoparticles, such as those listed hereinafter:
the particles thus generated from the substrate have a good mechanical anchorage to its surface;
it makes it possible to avoid implementing a high-temperature, wet process, or vacuum treatment, such that the process according to the invention may be applied with a simple item of equipment, without any particular constraint on the working environment;
the process may be used to functionalize a vast range of materials; and the material does not need to be in a particular crystalline form; in relation to a supply of nanoparticles, a health risk is reduced.

Furthermore, as the heating is then localized on the surface of the material, it is possible to treat solid parts of the material, but also coatings of said material deposited on substrates of another kind. Plastic, metallic, ceramic or composite parts may thus be functionalized if they are coated with a layer capable of being functionalized by the means described above.

For example, the laser emits very short light pulses, for example of duration between 1 femtosecond (1 fs=10^{'15} s) and 100 picoseconds (1 ps=10⁻¹² s), preferably between 20 fs and 10 ps.

For example, the surface is irradiated by laser pulses, for example focused directly on the surface, repeated at a repetition frequency between 1 kHz and 25 GHZ, in particular between 1 kHz and 20 GHz, for example between 1 kHz and 100 MHz, for example between 1 kHz and 500 KHz.

For example, the laser beam has a diameter generally of approximately 50 μm.

For example, the number of pulses required to treat a point of the surface (according to the size of the laser beam) is between 1 and 1000.

For example, the pulse fluence (energy received per unit of surface area) to generate nanoparticles, is less than the threshold fluence for the material in question (fluence from which the material is ablated), i.e., for example of the order of a fraction of J/cm². This fluence is dependent on the material to be treated and the other laser irradiation parameters.

For example, the laser treatment may be carried out in air, or in an inert environment.

In order to treat large surface areas, considerably greater in size than that of the laser beam, it is possible to scan the beam over the part using a scanner, or move the part opposite the beam using a turntable, in particular a motorized turntable.

In other words, the process may for example include a step of scanning the laser over the free surface of the substrate using a scanner, and/or a step of moving the free surface of the substrate in relation to the laser, using a turntable, in particular a motorized turntable.

In an example of implementation, the laser source used is configured to generate a pulsed laser beam, for example ultrashort (femtosecond or picosecond).

Furthermore, the ultrashort laser treatment does not require contacting of a solid or a liquid with the surface of the part, which makes it possible to treat parts of any shape, even complex.

The part to be treated, i.e., before the treatment described above, includes at least one substrate on the surface, i.e., a substrate which has a free surface.

The substrate to be treated includes at least on the surface a material in the solid state.

The material includes for example at least one element from columns 4, 5, 13 or 14 of the periodic classification of elements, in particular at least one element from among Ti, Zr, Hf (hafnium), Nb (niobium), Ta (tantalum), V (vanadium), Al (aluminum), or Si (silicon), preferably Ti and/or Zr; and at least one noble metal or one transition metal, in particular at least one noble metal or one transition metal from columns 8 to 11 of the periodic classification of elements, in particular at least one from among Au, Ag, Pt, Pd, Cu, Fe, Co, Ni, preferably Cu, Ag and/or Au.

During the implementation of the process, these elements diffuse on the surface to form at least one nanoparticle, and they have furthermore advantageous catalytic and/or antimicrobial and/or plasmonic properties.

The at least one element from columns 4, 5, 13 and 14 is thermodynamically less noble than the noble metal or transition metal, and has a low presence, or is absent, in the nanoparticles formed after irradiation. Nevertheless, it may form a layer of oxide of around one hundred nanometers on the surface of the treated material.

In an example of implementation, the material of the substrate before treatment is crystalline.

The substrate has for example a thickness of at least 50 nm, or 100 nm, for example between 50 nm and 5 μm, for example between 100 nm and 5 μm, for example between 500 nm and 5 μm.

In an example of implementation, a roughness of the substrate to be treated must be sufficiently low on the scale of the laser beam, for example, height fluctuations of the surface of the substrate on the scale of the laser spot must be included in the depth of field of the laser.

The part to be treated may entirely consist of the same material as the substrate (in other words only be formed of the substrate in its entire volume), or may include a support made of a first material covered on the surface with a coating which then consists of the substrate, having the features described above.

Plastic, metallic, ceramic or composite materials may thus be functionalized if they are coated with a layer that can be functionalized by the means described above.

The invention also relates, according to another aspect, to a part including at least one substrate made of a material having a chemical composition including at least one element from columns 4, 5, 13 or 14 of the periodic classification of elements, in particular at least one element from among Ti (titanium), Zr (zirconium), Hf (hafnium), Nb (niobium), Ta (tantalum), V (vanadium), Al (aluminum), or Si (silicon), preferably Ti and/or Zr; and at least one noble metal or one transition metal, in particular at least one noble metal or one transition metal from columns 8 to 11 of the periodic classification of elements, in particular at least one from among Au (gold), Ag (silver), Pt (platinum), Pd (palladium), Cu (copper), Fe (iron), Co (cobalt), Ni (nickel), preferably Cu, Ag and/or Au, and the substrate having a surface of which at least a part has a nanostructure including at least one nanoparticle, the at least one nanoparticle including at least the noble metal or the transition metal, and having a different chemical composition from that of the substrate.

Such a part is for example obtained by the process including at least some of the features described above.

Thus, for example, the at least one nanoparticle includes chemical elements having advantageous catalytic, antimicrobial, plasmonic and/or hydrophobic properties.

Nanoparticles thus formed have for example a low loss rate, for example under mechanical stress, or by immersion in a liquid, optionally with an ultrasound application.

Such a loss could be observed with an SEM microscopic observation (according to a top view as illustrated in FIG. 3B for example) before and after stress; the nanoparticle loss rate would for example be visible if the nanoparticles are not well anchored in the surface, as they may be thanks to the process according to the invention.

A layer of oxide of the at least one element from columns 4, 5, 13 and 14 is optionally formed on the surface of the substrate, for example under the nanoparticles.

For example, the substrate has a thickness (measured up to a vertex of a nanostructure) of at least 50 nm, or at least 500 nm, for example between 50 nm and 5 μm.

For example, the part is solid and only formed by the substrate.

In an embodiment example, the thickness of the substrate is between 100 nm and 5 μm, according to the type of part, a type and a surface condition of an optional support coated with the substrate, and a sought functionality (resistance to abrasion, corrosion, design, etc.).

For example, a nanoparticle thus obtained has a characteristic size, for example a mean diameter, between 1 nm and 200 nm.

For example, that at least one nanoparticle including the at least one noble metal or transition metal includes one from among Au, Ag, Pt, Pd, Cu, Fe, Co, or Ni, preferably Cu, Ag and/or Au.

For example, a nanoparticle is crystallized.

According to an advantageous option, the nanostructure furthermore includes periodic undulations.

Such periodic undulations are also known as LIPPS (“Laser-Induced periodic surface structures”).

For example, the periodic undulations are repeated periodically on the surface, for example according to a spatial periodicity generally between 200 nm and 1000 nm, depending on the material of the treated substrate and the irradiation parameters used.

According to a specific example, the at least one nanoparticle is formed on a ridge (or a vertex) of such an undulation.

### DETAILED DESCRIPTION

The invention, according to an embodiment example, will be understood clearly and its advantages will become more apparent on reading the following detailed description, given as an indication and in no way limitation, with reference to the appended drawings wherein:

FIG. 1 schematically illustrates a difference in anchorage of a nanoparticle on a substrate, according to whether it is obtained with a deposition process (FIG. 1A) or with a generation process from the support material (FIG. 1B);

FIG. 2 schematically illustrates a part obtained with the process according to an implementation of the invention, the part including any support (metallic, ceramic, composite or plastic) coated with a substrate on the surface from which nanoparticles are generated;

FIG. 3 shows an SEM (scanning electron microscope) photo of the nanostructured surface obtained with a process according to a first example of implementation of the invention;

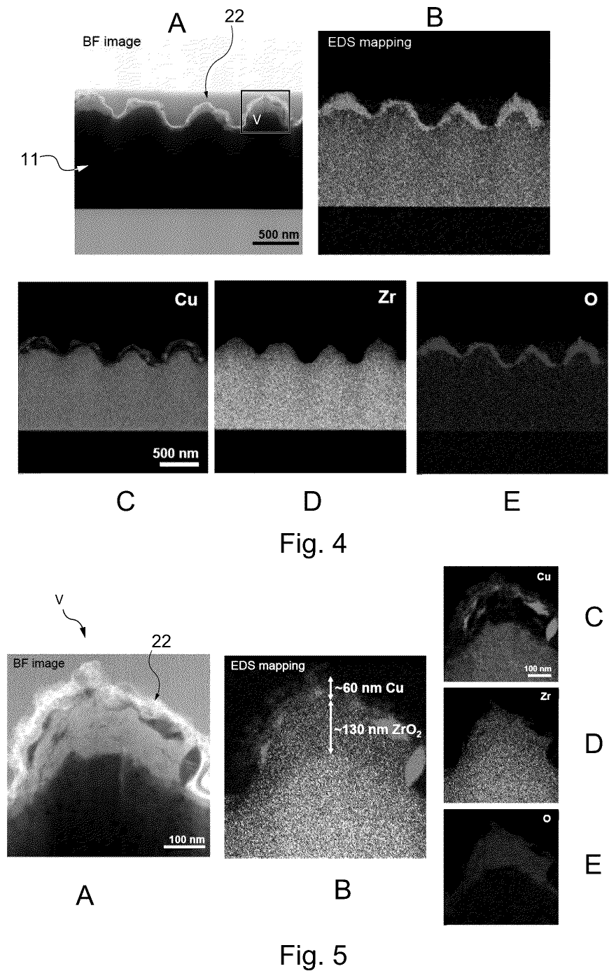

FIG. 4 illustrates the chemical segregation effect obtained with the process according to the first example of implementation of the invention as illustrated in FIG. 3;

FIG. 5 shows in more detail the top of a ridge showing the Cu nanoparticles on the thin layer of ZrO₂;

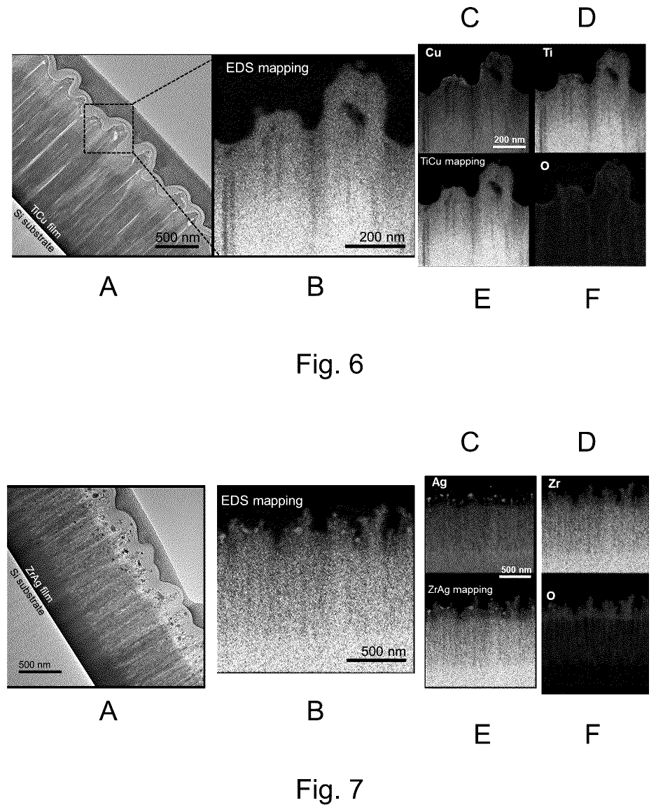

FIG. 6 illustrates a surface obtained by the implementation of the process according to a third example of implementation of the invention; and

FIG. 7 illustrates a surface obtained by the implementation of the process according to a fourth example of implementation of the invention.

The process according to an implementation of the invention makes it possible to functionalize a material by generating nanostructures on its surface, and in particular nanoparticles.

FIG. 1 illustrates the difference in principle between nanoparticles 2 added on the surface of a substrate 1, as with a process of the prior art (illustrated in FIG. 1A), and nanoparticles 12 generated from a substrate 11, as with a process according to an implementation of the invention (illustrated in FIG. 1B).

It is clear from the scenario of FIG. 1B that the nanoparticles 12 are then better anchored to the surface of the substrate 11.

To implement the process according to an implementation of the invention a part 10 to be treated is provided including at least one substrate 11 on the surface of which the process is applied.

FIG. 2 schematically illustrates such a part 10 including the substrate 11 on the surface. This figure shows that such a part 10 to be treated may also include any support 13 (for example metallic, ceramic, composite or plastic) which is then coated with the substrate 11.

A part to be treated may thus be a massive solid having the same composition in its entire volume, or be composed of a first support material 13 covered on the surface with a coating having the features described here (i.e., the substrate 11).

Plastic, metallic, ceramic or composite support materials may thus be functionalized.

In this example, the substrate 11 includes a metal alloy AB, formed from the elements A and B.

Under the effect of a localized heating induced by a laser treatment according to an example of implementation of the process, the element A of the material of the substrate 11 diffuses on the surface of the substrate 11 and nanoparticles 12 are formed, mainly based on the element A.

In particular, the elements forming the nanoparticles 12 are elements known for their tendency to form nanoparticles: if a surface of the substrate including such an element is irradiated by femtosecond (or picosecond) laser for example, it is common that the nanoparticles of the same element be observed on the surface (e.g.: Ag nanoparticles on an irradiated Ag surface).

Thus, these nanoparticles 12 are composed of some of the chemical elements of the treated material of the substrate, but has a different chemical composition from it (chemical segregation effect).

Such nanoparticles 12 are then well anchored in the substrate 11, as represented in FIG. 1A.

The process used to generate these nanoparticles 12, according to an implementation considered here, is irradiation by an ultrashort (femtosecond or picosecond) laser beam of the surface of the material of the substrate 11.

An ultrashort laser emits very short light pulses, for example of durations between 1 fs (=10⁻¹⁵ s) and 100 ps.

The wavelength of the laser is for example here between 100 nm and 5000 nm, or for example between 400 nm and 1030 nm.

The surface is irradiated by laser pulses repeated at a frequency here between 1 KHz and 25 GHz.

The number of pulses used to treat a point of the surface (corresponding to a laser beam size of approximately 50 μm) is here between 1 and 1000.

The pulse fluence (energy received per unit of surface area) to generate nanostructures and in particular nanoparticles is preferably less than the threshold fluence for the material in question (fluence from which the material is ablated), for example of the order of a fraction of J/cm². This fluence is dependent on the material to be treated and the other femtosecond laser irradiation parameters (likewise with a picosecond laser).

The laser treatment may be carried out in air or in an inert atmosphere.

These ultrashort laser irradiations induce a localized heating of the treated surface: the laser-material interaction takes place over a typical depth of around fifteen nanometers, and the energy supplied is propagated in the form of heat and pressure waves over a typical depth of around one hundred nanometers in the treated material.

Under the effect of this treatment, the material from the surface (on a scale of around one hundred nanometers) is decomposed, and one or more elements forming the initial material diffuse toward the surface to form nanoparticles.

In order to treat large surfaces, of considerably greater size than that of the laser beam, it is possible, for example, to scan the beam over the part using a scanner, or move the part facing the beam using a turntable.

The material of the substrate to be treated is preferably in the solid state, and at least formed of metallic elements.

In particular, this material includes for example at least one noble metal or one transition metal from columns 8 to 11 of the periodic classification (for example: Au, Ag, Pt, Pd, Cu, Fe, Co, Ni), preferably Cu, Ag and/or Au. These elements then rise on the surface to form nanoparticles. These elements have advantageous catalytic and/or antimicrobial and/or plasmonic properties.

It possibly also includes at least one element (for example metallic or non-metallic) from columns 4, 5, 13 and 14 of the periodic classification (selected in particular from among Ti, Zr, Hf, Nb, Ta, V, Al, Si), preferably Ti and/or Zr. These elements are thermodynamically less noble than the elements cited above, and are found more rarely in the nanoparticles formed after irradiation. On the other hand, they may optionally form a layer of oxide on the surface of the treated material, possibly of a thickness up to around one hundred nanometers.

The treated material is optionally crystalline.

The surface of the material to be treated preferably has a sufficiently low roughness on the scale of the laser beam (of characteristic size of around ten μm).

### Example 1: treatment of a Part Including Amorphous Zr_{0.5}Cu_{0.5} Coating Deposition

According to a first example of implementation, the process is applied to a part including a Zr_{0.5}Cu_{0.5} coating.

In this example, a stainless steel metallic part is provided, which then forms a support here.

To functionalize a surface of the part, the process includes here a preliminary step of depositing a coating including the elements described hereinafter.

A layer of 50/50 atomic percentage ZrCu alloy is applied on the support by vacuum deposition.

To do this, the support is for example cleaned (degreased, rinsed and blown), then fastened to a substrate holder and placed in a vacuum deposition machine.

A degassing and a heating of the machine with the support in place makes it possible to attain pressures of the order of 10⁻⁷ to 10⁻⁵ mbar in the deposition machine. The support is stripped in order to remove any oxide layer on the surface. Then, a solid target of the sought composition (here 50/50 ZrCu) is sputtered by magnetron cathode sputtering, opposite the part to be treated (here the support). A coating of approximately 2 μm of amorphous 50/50 ZrCu alloy is thus obtained on the surface of the stainless steel support. The same alloy may also be obtained by sputtering two metallic targets (co-sputtering process).

The coating then forms the substrate which will undergo steps of the process according to an implementation of the invention to generate nanoparticles.

A femtosecond laser treatment (with a wavelength of approximately 800 nm) is then applied on at least one targeted zone of the surface of the substrate; such a zone is for example of centimetric size.

One hundred pulses of duration 50 fs, and of fluence 0.1 J/cm² are applied per irradiated point, at a frequency of 1 kHz. The zone to be treated is for example scanned by the beam using a motorized turntable.

FIG. 3 shows an SEM view of a surface of a substrate 11 of which one part 11a has been treated with the process according to the first example of implementation of the invention described above.

In FIG. 3A, the irradiated part 11a has a width of approximately 30 μm; at either end (at the top and bottom in FIG. 3A), the surface has not undergone the process according to the invention.

FIG. 3B shows a detail in FIG. 3A.

This figure shows that the irradiation of the surface of the substrate has generated a nanostructure including periodic undulations 22 (LIPPS-Laser-Induced periodic surface structures) and nanoparticles 12.

The spatial periodicity of the undulations 22 is generally between 200 nm and 1000 nm according to the material treated and the irradiation parameters of the laser used.

Here, the undulations 22 have a mean height of approximately 300 nm (measured between a bottom of a valley and an adjacent ridge) and a lateral characteristic size (thickness) of approximately 500 nm.

The nanoparticles 12 are here more particularly present on the undulations 22, in particular on a ridge of the undulations 22.

The nanoparticles have for example a characteristic size (mean diameter for example) between 10 nm and 200 nm and are for example crystallized. Here, they have a characteristic size of approximately 50 nm.

FIGS. 4 and 5 show cross-sections of the substrate of FIG. 3.

In FIG. 4, FIG. 4A shows a TEM (transmission electron microscopy) image, FIG. 4B shows EDS (energy dispersion spectroscopy) mapping, and Images 4C, 4D and 4E respectively illustrate the presence of Cu, Zr and O.

FIG. 5 shows in more detail the top of an undulation 22. FIG. 5A shows a TEM image of the top of an undulation 22, FIG. 5B shows EDS mapping of FIG. 5A, and Images 5C, 5D and 5E give chemical mapping of Cu, Zr and O, respectively.

According to these FIGS. 4 and 5, it is apparent that the undulations are formed essentially of the base material (ZrCu layer), whereas the upper part of the undulations includes a layer of around one hundred nanometers of ZrO₂. Finally, partially anchored in this layer of ZrO₂, nanoparticles of pure, crystallized Cu are present on the undulations.

FIG. 5 shows in more detail the top of an undulation, showing more clearly the Cu nanoparticles (for example, FIG. 5C) on the thin layer of ZrO₂ (the presence of O being more visible in FIG. 5E). Furthermore, FIG. 5b indicates that the thin layer of ZrO₂ measures approximately 130 nm in thickness, whereas the Cu nanoparticles form a layer of approximately 60 nm in thickness.

The process described above thus makes it possible to generate Cu nanoparticles on the surface of a metallic part, moreover protected by a thin layer of ZrO₂. Catalytic, antimicrobial, plasmonic, hydrophobic functions (by the nanostructure) may thus be added to the treated part, with potential applications linked with these functions.

### Examples 2: Atomic Ratio Effect and Numbers of Elements Present in the Material

The effects of the process according to an implementation of the invention may be obtained for other amorphous substrates based on Zr and Cu: for example, a binary alloy ZrₓCu₁₋ₓ where x is between 0.35 and 0.65, a ternary alloy ZrₓCu_{1-x-y}Ta_{y}, for the same range of values of x, and for y<0.15, or for a more complex alloy, such as Zr_{52.5}Al₁₀Cu₂₇Ni₈Ti_{2.5}.

To form the substrate, these materials may be made in the form of thin layers, for example by magnetron cathode sputtering, either of a solid target of the sought composition, or of several solid targets. In the second scenario (co-sputtering of several targets), the powers applied on the different targets are adjusted so as to obtain the sought composition for the layer thus produced. Thus, to produce an alloy ZrₓCu_{1-x-y}Ta_{y}, three sputtering targets, respectively of Zr, Cu and Ta may be used, and the power ratios between these targets are adjusted according to the sought x and y ratios.

The laser irradiation parameters are adjusted according to the composition of the alloy to obtain the nanostructuring (nanoparticles, and optionally undulations) and chemical segregation effect.

In these different scenarios, after laser irradiation treatment, the formation of Cu nanoparticles on the surface of the alloy is observed, the size and number of which are dependent on the proportion of Cu in the alloy of the substrate.

Alloys having a strong tendency to remain amorphous, for example complex alloys, for example of composition Zr_{52.5}Al₁₀Cu₂₇Ni₈Ti_{2.5} or Zr_{41.2}Ti_{13.8}Cu_{12.5}Ni₁₀Be_{22.5}, may be obtained in massive solid form (of limited dimensions), in the amorphous state.

The laser irradiation may be performed directly on the massive solid according to the same protocol as that described above, and a similar result to that for a layer of the same, or identical, material is obtained.

Ultrashort laser irradiation inducing a localized heating effect on the surface of the treated material, the chemical nature of that located below (support of different chemical nature, or homogeneous material) has no influence on the treatment and its effect.

### Example 3: Effect of Chemical Nature of the Elements of the Alloy of the Substrate and of Irradiation Environment

Substrates of other binary alloys, of compositions as described above, may be functionalized.

The irradiation of a substrate of Ti_{0.5}Cu_{0.5} thus results in the generation of Cu nanoparticles, that of Zr_{0.66}Ag_{0.33} in Ag nanoparticles, and that of Zr_{0.5}Au_{0.5}, in Au nanoparticles.

According to the material of the substrate and the laser treatment environment, the nanoparticles generated may be located either above for one the oxide formed by the passivatable element of the alloy, and be anchored in the oxide, or be located below (or in) a thin layer of this oxide.

Thus, the first scenario is for example obtained with a laser treatment in air of a Zr_{0.5}Cu_{0.5 alloy}: the Cu nanoparticles generated are on the surface and anchored in a layer of ZrO₂. The oxygen then stems from the passivation of the material after reventing. This is also the case for a laser treatment in an inert environment of a Ti_{0.5}Cu_{0.5} alloy: the Cu nanoparticles are anchored in a layer of TiO₂.

The second scenario is for example obtained for a laser treatment in air of a Ti_{0.5}Cu_{0.5} alloy: the Cu nanoparticles are located under a very thin layer of TiO₂.

This is for example illustrated by FIG. 6.

In this figure, FIG. 6A shows a TEM image of a cross-section of a Ti_{0.5}Cu_{0.5} substrate on an Si support, FIG. 6B shows EDS mapping of a detail of FIG. 6A, and Images 6C, 6D, 6E and 6F illustrate the presence of Cu, Ti, TiCu and O, respectively.

The EDS mapping of FIG. 6B shows a series of Cu nanoparticles, under a thin layer of TiO₂.

These figures show that after laser treatment in air of a Ti_{0.5}Cu_{0.5} alloy, the Cu nanoparticles are located in, or below, a thin layer of TiO₂ formed on the surface of the substrate.

### Examples 4: Effect of Crystalline Nature of the Treated Material

The treated substrates may not be amorphous, unlike the amorphous alloys of ZrₓCu₁₋ₓ, ZrₓCu_{1-x-y}Ta_{y}, Zr_{52.5}Al₁₀Cu₂₇Ni₈Ti_{2.5}, Ti_{0.5}Cu_{0.5} described above.

Substrates of Zr_{0.66}Ag_{0.33} and Zr_{0.5}Au_{0.5}, having X-ray diffraction crystalline phase signatures before laser treatment, may have the same surface nanoparticle generation and chemical segregation effect after laser irradiation.

This is for example illustrated by FIG. 7.

In this figure, FIG. 7A shows a TEM image of a cross-section of a Zr_{0.66}Ag_{0.33} substrate on an Si support, FIG. 7B shows EDS mapping of a detail of FIG. 7A, and Images 7C, 7D, 7E and 7F illustrate the presence of Ag, Zr, ZrAg and O, respectively.

The EDS mapping of FIG. 7B shows that after laser treatment in air of an alloy Zr_{0.66}Ag_{0.33}, Ag nanoparticles are formed on a layer of ZrO₂ formed on the surface of the nanocrystalline alloy Zr_{0.66}Ag_{0.33}.

1. A process for generating nanoparticles on the surface of a substrate, the process including:
a step of providing the substrate having a free surface, the substrate being made of a material having a chemical composition including:
at least one element from columns 4, 5, 13 and 14 of the periodic classification of elements;
at least one noble metal or one transition metal;
a step of irradiating at least a part of the free surface of the substrate by a laser radiation source producing a pulsed radiation, with a pulse time between 1 fs and 100 ps, a pulse fluence between 0.01 J/cm² and 100 J/cm², a wavelength between 100 nm and 5000 nm, and a number of pulses per point treated between 1 and 1000; and
a step of generating at least one nanoparticle on the free surface of the substrate from the material of the substrate, the at least one nanoparticle including at least the noble metal or the transition metal, and having a different chemical composition from that of the substrate.

2. The process according to claim 1, wherein the laser emits pulses of duration between 1 fs and 100 ps.

3. The process according to claim 1, wherein the surface is irradiated by laser pulses repeated at a repetition frequency between 1 kHz and 25GHz.

4. The process according to claim 1, including a step of scanning the laser over the free surface of the substrate using a scanner, and/or a step of moving the free surface of the substrate in relation to the laser, using a turntable.

5. A part including at least one substrate made of a material having a chemical composition including at least:
one element from columns 4, 5, 13 or 14 of the periodic classification of elements, and
one noble metal or one transition metal,
and the substrate having a surface of which at least a part has a nanostructure including at least one nanoparticle, the at least one nanoparticle including at least the noble metal or the transition metal, and having a different chemical composition from that of the substrate.

6. The part according to claim 5, wherein the at least one element from columns 4, 5, 13 or 14 of the periodic classification of elements is selected from among Ti (titanium), Zr (zirconium), Hf (hafnium), Nb (niobium), Ta (tantalum), V (vanadium), Al (aluminum), or Si (silicon).

7. The part according to claim 5, wherein the at least one noble metal or transition metal from columns 8 to 11 of the periodic classification of elements is selected from among Au (gold), Ag (silver), Pt (platinum), Pd (palladium), Cu (copper), Fe (iron), Co (cobalt), Ni (nickel).

8. The part according to claim 5, wherein the at least one nanoparticle has a characteristic size between 1 nm and 200 nm.

9. The part according to claim 5, wherein the at least one nanoparticle including the at least one noble metal or transition metal includes one from among Au, Ag, Pt, Pd, Cu, Fe, Co, or Ni.

10. The part according to claim 5, wherein the at least one nanoparticle is crystallized.

11. The part according to claim 5, wherein the nanostructure furthermore includes periodic undulations.

12. The part according to claim 5, wherein the periodic undulations are repeated periodically on the surface according to a spatial periodicity between 200 nm and 1000 nm.

13. The part according to claim 11, wherein the at least one nanoparticle is formed on a ridge of one of the undulations.

14. The part according to claim 5, wherein only a part of the surface of the substrate has the nanostructure.

15. The part according to claim 5, wherein the at least one element from columns 4, 5, 13 and 14 forms a layer of oxide on the surface of the treated material.

16. The process according to claim 2, wherein the surface is irradiated by laser pulses repeated at a repetition frequency between 1 kHz and 25 GHz.

17. The process according to claim 16, including a step of scanning the laser over the free surface of the substrate using a scanner, and/or a step of moving the free surface of the substrate in relation to the laser, using a motorized turntable.
